(19) United States
(12) Patent Application Publication
(10) Pub. No.: US 2011/0303148 A1
(43) Pub. Date: Dec. 15, 2011

(54) FULL-ENCLOSURE, CONTROLLED-FLOW MINI-ENVIRONMENT FOR THIN FILM CHAMBERS

(76) Inventors: Jun XIE, San Jose, CA (US); Kevin P. Fairbairn, Los Gatos, CA (US); Charles Liu, Los Altos, CA (US); Patrick Leahey, San Jose, CA (US); Robert L. Ruck, San Jose, CA (US); Terry Bluck, Santa Clara, CA (US)

(21) Appl. No.: 13/157,077

(22) Filed: Jun. 9, 2011

Related U.S. Application Data
(60) Provisional application No. 61/353,164, filed on Jun. 9, 2010.

(51) Int. Cl. C23C 16/50

(52) U.S. Cl. 118/719; 118/723 R

(57) ABSTRACT

An enclosure for generating a secondary environment within a processing chamber for coating a substrate. An enclosure wall forms a secondary environment encompassing the coating source, plasma, and the substrate, and separating them from interior of the processing chamber. The enclosure wall includes a plurality of pumping channels for diverting gaseous flow away from the substrate. The channels have an intake of larger diameter from the exhaust opening and are oriented at an angle with the intake opening pointing away from the deposition source. A movable seal enables transport of the substrate in open position and processing the substrate in closed position. The seal may be formed as a labyrinth seal to avoid particle generation from a standard contact seal.

### RELATED APPLICATIONS

This application claims priority benefit of U.S. Provisional Application Ser. No. 61/353,164, filed on Jun. 9, 2010, the content of which is incorporated herein in its entirety by reference.

### BACKGROUND

1. Field of the Application

This application is in the field of thin film deposition, such as physical vapor deposition (PVD), Plasma Enhanced Chemical Vapor Deposition, (PECVD), etc.

2. Related Art

In state-of-the-art microelectronics (semiconductor ICs, flat panel displays, computer hard-disk drive, etc.) manufacturing, a majority of the critical process steps, such as thin film deposition (coating) and etching, are carried out in specially constructed vacuum apparatus that provide a clean and controlled environment free of ambient contaminants so as to ensure process controllability, stability, and repeatability.

FIG. 1 is a schematic of a prior art processing apparatus, which, in this specific example is a PVD chamber. A fairly high vacuum level, typically between 10⁻³ Torr and 10⁻⁹ Torr, is maintained within such apparatus by one or more vacuum pumps (mechanical pumps, diffusion pumps, ion pumps, cryopumps, turbomolecular pumps, etc.). Plasma is maintained between a target and the processed substrate. The plasma species impinge and eject atoms from the target, which are then deposited on the substrate to form the desired thin film.

In practice, even under the best vacuum environment, a small amount of various gaseous species, such as hydrogen (H₂), water (H₂O), nitrogen (N₂), carbon monoxide (CO), and carbon dioxide (CO₂), are always present within these apparatus. These gaseous species, sometimes called residual gas, come from the following sources, i) leaks to the ambient environment, ii) outgassing from the system components such as stainless steel, aluminum or polymer insulator parts, and/or iii) permeation through elastomer seals. Various practices attempt to reduce the amount of residual gases. For example, careful leak-checking could rectify most leaks and the use of electro-polished stainless steel and OFHC (oxygen-free high thermal conductivity) copper gasket seals, in conjunction with long bake-out at elevated temperature. While these practices could help reduce outgassing and permeation, a small but yet detectable amount of aforementioned residual gas would always be present albeit at a much lower level.

For a high productivity manufacturing system common in the microelectronics industries, cost, throughput and ease-of-maintenance requirements make some of the high vacuum solutions, such as long bake-out or single-use OFHC copper gaskets, inapplicable. In addition, a high productivity manufacturing system inevitably has to process a large number of substrates (silicon wafers, glass panels, or glass or aluminum disks) every hour for days on end, exposing itself to ambient contaminants which may either migrate through the loading/unloading chambers or enter the system by clinging onto incoming substrates. In short, there is always a small amount of gaseous contaminants present within any given vacuum apparatus, including high productivity manufacturing systems in the microelectronics industries.

With the unrelenting advances of microelectronics manufacturing technologies, the design rules of semiconductor ICs approach the 18 nm nodes, following the ever-extending Moore's Law, while hard-disk drives are packing hundreds of billions bits (Gigabits) of data on a mere square inch of disk surface. The trace contaminants in the vacuum processing, now more than ever, are of great concern. In the hard-disk drive industry, for example, a disk is methodically coated in sequence a number of ultra-thin metal film layers (tens of nanometers in thickness each), which are extremely susceptible to the trace contaminants, in particular H₂O. The H₂O molecules react readily with fresh deposited metallic films, such as Cr, Ti, Al, and Ni, to form oxides or sub-oxides, and alter the compositional as well as physical integrity of the metal thin films. The film properties, such as grain size or crystalline orientation, when compromised by contamination, adversely affect the performance of the end product.

Consequently, to ensure the deposited film quality it becomes a top priority to prevent the trace contaminants in the vacuum system, especially H₂O, from interacting with the deposited films during a deposition process. Known methods include one or a combination of the following: I) increasing pumping capacity, II) installing additional water-pumping capability (such as cryo-panel or Meissner coils), III) introducing a greater flow rate of inert process gas (argon) to “sweep” the contaminants into the pumps, IV) utilizing UV irradiation to promote water desorption, or V) erecting a barrier around the deposition zone between the substrate and the plasma source (sputter target). These methods provide some limited benefits. Increasing pumping capacity and/or adding water-pumping capability (Methods I and II) accelerate the removal of some contaminants permeating into the chamber but has little effect on contaminants adsorbed on the chamber wall whose evacuation rate, particularly that of H₂O, is very much dictated by the desorption rate. At ambient temperature, most H₂O molecules adsorbed on the chamber wall do not have enough energy to escape into the vacuum. Only when a great quantity of inert process gas (such as argon) is introduced, the collisions of the impinging argon atoms would dislodge H₂O molecules from the chamber wall (Method III). By absorbing UV photons emitted from a UV source (Method IV) or the plasma during processing, H₂O molecules may gain energy and desorb from the chamber wall. By themselves, Methods III and IV could elevate partial pressures of contaminants. To avoid such negative effect, Method III or IV tends to be employed in association with Method I or II. Still, the benefits produced by Methods Ito IV are limited since, more often than not, the substrate and the plasma source are centrally located in the vacuum chamber whereas the pumping paths are arranged in the peripheral. A freed H₂O molecule from the chamber wall is more likely to enter and land on the substrate than to reach the pump.

Method V attempts to create a so-called mini-environment to keep out the residual-gas contaminants ever present within the vacuum environment by erecting a barrier around the substrate and the sputter target, forming virtually a “chamber within a chamber”. This approach, illustrated in FIG. 2, is challenging to implement in practice because it has to maintain a gap between the edge of the substrate and the lip of the enclosure, providing only partial protection at best. As shown in FIG. 3, the width of the gap, g, would have to be as narrow as possible to keep the contaminants out, but also be wide enough to maintain a decent pumping conductance to enable maintaining the required high vacuum state. As a result, contaminants tend to collect at the edge of the substrate, just as dust collects at the edge of fan blades.

On the other hand, since the process gas is introduced outside of the enclosure and flows into the enclosure through the narrow gap, the contaminants are equally likely to squeeze through the gap and into the mini-environment. More importantly, with the location of the gap right next to the substrate, any contaminant entering the mini-environment is most likely to land on the substrate, increasing the chance of contamination of the deposited film.

FIGS. 1-3 illustrate a processing chamber that processes only a single surface of the substrate. Such chambers are mostly used for processing integrated circuits, solar cells, LED's, flat panel displays, etc. However, as indicated above, the gas contaminants issue also affects fabrication of disks used in hard disk drives (HDD). FIG. 4 is a schematic of a prior art processing apparatus which enables simultaneous processing of two sides of a substrate, such as a disk for HDD's. The chamber 400 is somewhat similar to the chambers of FIGS. 1-3, except that plasma processing 430 is performed on both sides of the disk 425 simultaneously. Also, in state of the art disk fabrication systems the disk 425 is mounted on a carrier 435 and is processed while held by the carrier, generally in a vertical orientation. As illustrated, provisions are made for gas to flow to maintain vacuum condition. However, leakage, outgassing, and permeation still presents a contamination problem in such systems.

Accordingly, a solution is needed to prevent residual gas contamination of deposited thin film in plasma processing apparatus.

### SUMMARY

The following summary is included in order to provide a basic understanding of some aspects and features of the disclosure. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Embodiments of the invention enables creating a pristine clean environment for ultrapure thin film deposition by constructing an enclosure around the essential process components, such as the plasma sources, substrates, and working gas inlets, while diverting the gas flow to evacuation channels.

According to embodiments of the invention, an enclosure for generating a secondary environment within a vacuum processing chamber for coating a substrate is provided. The enclosure comprises an enclosure wall forming a secondary environment within the interior of the processing chamber and encompassing the coating source (e.g. sputtering target), the plasma, and the substrate, and separating them from the interior of the processing chamber. The enclosure wall has a plurality of pumping channels positioned remotely from the substrate, for diverting gaseous flow away from the substrate. The pumping channels may be made in a “V” or other shapes that restricts direct line-of-sight flow. Also, the diameter of the channels may be larger at the opening to the interior of the enclosure and smaller at the opening to the processing chamber. For chambers utilizing coating source, such as sputtering target, the pumping channels are oriented away from the target and facing the substrate to be processed. In this manner, coating material from the target will not enter the channels, while coating material scattered from the substrate will enter the channels.

A movable seal opens to transport the substrate to the secondary environment and closes to seal the secondary environment about the substrate. A gas inlet introduces process gas into the secondary environment so as to ensure positive pressure gradient inside the secondary environment versus that outside of the secondary environment.

Embodiment of the invention also provide for a plasma processing chamber, such as, e.g., a PVD chamber, having the enclosure described above.

### BRIEF DESCRIPTION OF THE DRAWINGS

Other aspects and features of the invention would be apparent from the detailed description, which is made with reference to the following drawings. It should be appreciated that the detailed description and the drawings provides various non-limiting examples of various embodiments of the invention, which is defined by the appended claims.

FIG. 1 is a schematic of a prior art processing apparatus.

FIG. 2 is a schematic of a prior art apparatus having a shield.

FIG. 3 is a schematic of a prior art apparatus having a shield, and illustrating the causes of contamination in such systems in spite of the shield.

FIG. 4 is a schematic of a prior art processing apparatus which enables simultaneous processing of two sides of a substrate, such as a disk for hard disk drive (HDD).

FIG. 5 illustrates an embodiment of the invention having the sealed mini-environment and flow diversion features.

FIG. 6 illustrates an embodiment of the invention implemented in a chamber for simultaneous processing of both sides of the substrate.

FIG. 7 illustrates an embodiment of the secondary enclosure.

FIG. 8 illustrates an example of the pumping channel according to an embodiment of the invention.

FIG. 9 illustrates a cross-section of a secondary enclosure wall according to an embodiment of the invention.

FIGS. 10A and 10B illustrate an actuated seal according to an embodiment of the invention.

FIG. 11 illustrates a secondary enclosure having a movable seal, according to an embodiment of the invention.

FIG. 12 illustrates an embodiment of the secondary enclosure with the labyrinth seal.

FIG. 13 illustrates the construction of the enclosure wall of two parts with mating holes, according to an embodiment of the invention.

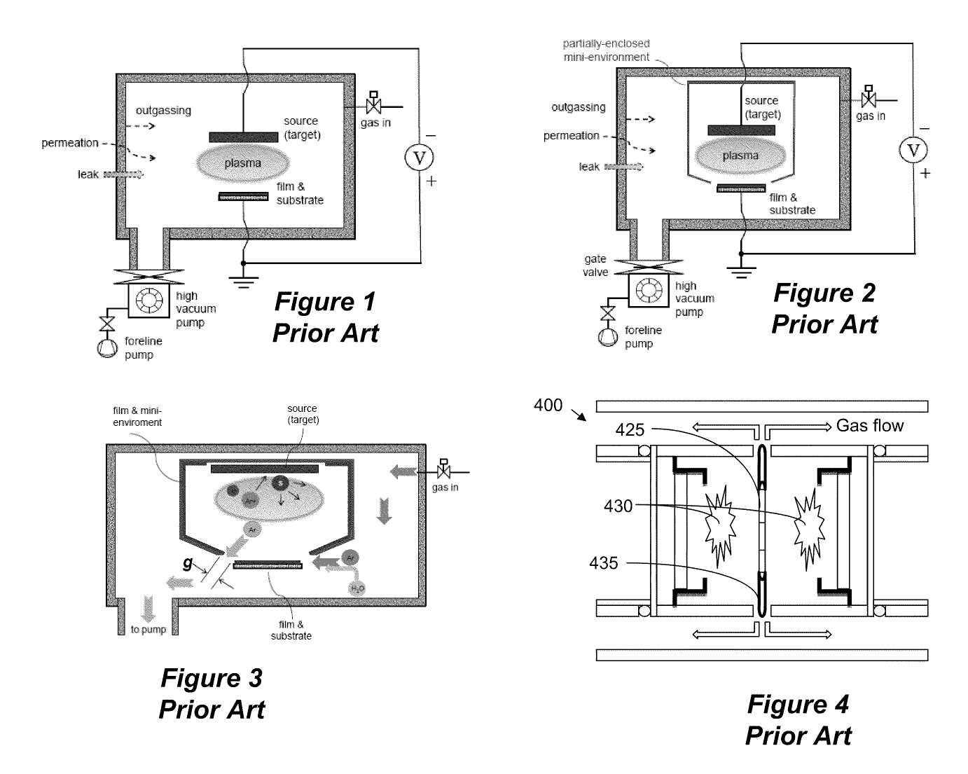

### DETAILED DESCRIPTION

According to embodiments of the invention, a system having two elements is provided in order to enable ultra-pure processing environment. The first is an enclosure that seals off a volume around the deposition source and the substrate, creating a fully enclosed mini-environment. This separates the essential participants of the deposition processes from the rest of the larger process chamber including, in particular, potential sources of contaminants (such as leaks, outgassing, permeation, etc.). The second is a series of holes or channels of pre-determined sizes and shapes through the wall of the enclosure that facilitate the diversion and evacuation of the gases or byproducts from the enclosure in a controlled/desired manner while minimizing the probability of outside contaminants entering the enclosure. In combination, the movable enclosure and the exhaust channels provide a method for controlled-flow of gases, promoting outward gas flow from the mini-environment and preventing contaminants from entering it.

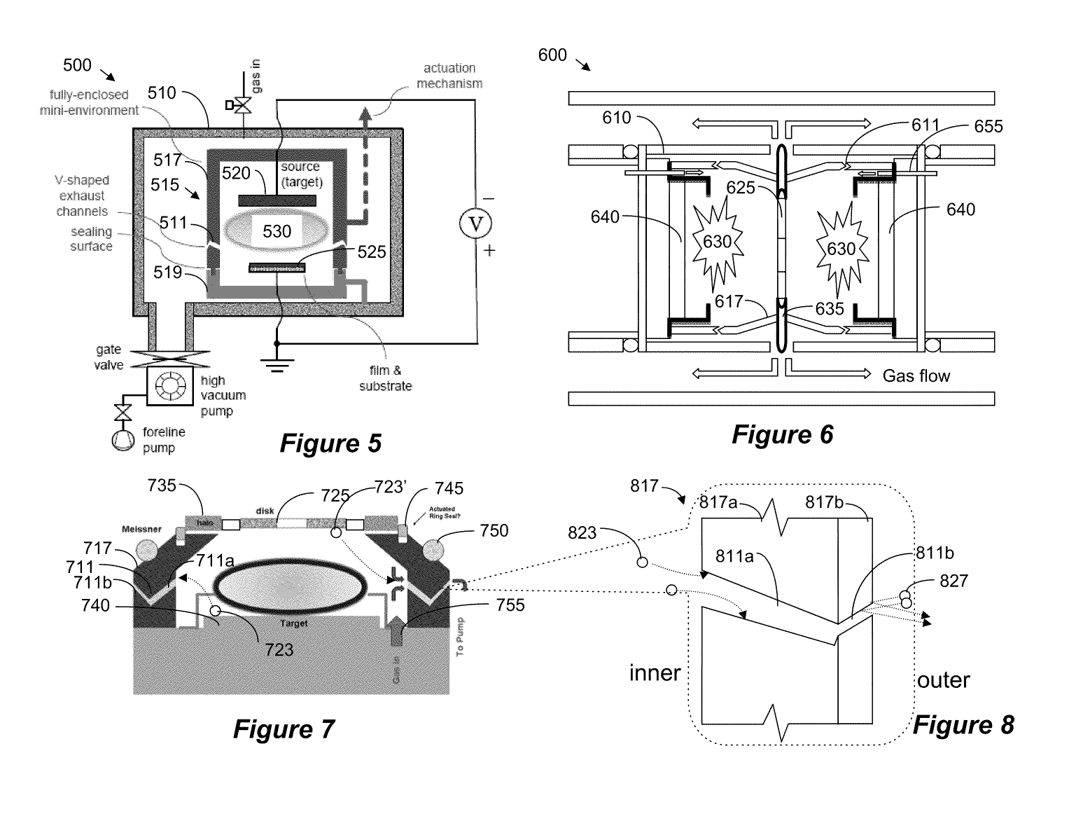

FIG. 5 illustrates an embodiment of the invention having the sealed mini-environment and flow diversion features. In FIG. 5, the exterior enclosure 510 of the chamber 500 is coupled to a vacuum pump 505 to evacuate the interior of the chamber. A secondary enclosure 515 is positioned inside the chamber 500 and forms a secondary, mini-environment within the interior of chamber 500. Enclosure 515 completely encloses the sputtering target 520, the substrate 525, and the plasma 530. Enclosure 515 is generally made of two parts, 517 and 519, at least one of which is movable to enable transporting of the substrate 525 in a retracted position, and processing of the substrate in its engaged position when engaging seal 513. At least one of parts 517 and 519 includes evacuation holes or channels 511. In the embodiment shown in FIG. 5, the evacuation channels 511 are in a V-shape, so as to enable pumping while preventing transport of contaminants into the mini-environment.

FIG. 6 illustrates an embodiment of the invention implemented in a chamber for simultaneous processing of both sides of the substrate, such as a HDD disk. In FIG. 6 disk 625 is held vertically by carrier 635. Plasma 630 is ignited between each surface of the disk 625 and a corresponding sputtering target 640. The disk 625, plasma 630 and carrier 635 are enclosed by secondary enclosure 617, which forms seal to the carrier 635. Enclosure 617 includes pumping channels 611, which are situated away from the surface of the disk 625. Consequently, pumping flow is diverted away from the surface of the disk, so as to avoid contamination of the disk. Also, unlike the prior art, in the embodiment of FIG. 6 the gas used for the plasma processing is injected directly into the secondary enclosure 617 by injectors 655.

FIG. 7 illustrates an embodiment of the secondary enclosure, such as the one that can be used in the embodiments of FIGS. 5 and 6. In FIG. 7 only one side of the substrate is shown processed, but by mirroring the structures shown in FIG. 7, both sides of the substrate can be processed simultaneously. In FIG. 7, substrate 725 is held by carrier 735. Movable seal 745 seals the gap between the carrier 735 and the wall 717 of the secondary enclosure. In this manner, no flow is generated on the surface of the substrate 625. Pumping channels 711 are provided on the sidewall 717 of the secondary enclosure. The pumping channels 717 are provided in a position away from the surface of the disk. In this embodiment, the pumping channels 711 are in a “V” shape, to prevent contaminants from entering the secondary chamber's enclosure. Also, in this embodiment the channels 711 are made in two parts, a first part, 711b, which is an oblique hole leading from the exterior of the wall 717 and is of small diameter to prevent contaminants from flowing thereto, and a second part, 711a, which is an oblique hole leading from the interior of wall 717 in a somewhat opposite angle to that of hole 711b, but is of larger diameter. Hole 711a is of larger diameter so as to prevent various deposits from target 740 from occluding the hole after a short time of usage. Also shown in FIG. 7 is an optional Meissner trap positioned on the exterior of the secondary enclosure, so as to remove water vapors.

Another feature illustrated in FIG. 7 is the orientation of the interior pumping channels 711a. As illustrated, the interior pumping channels 711a are angled in an orientation facing the substrate and away from the thin-film source 723. In this manner, it is unlikely that coating material 723 from the thin-film source enter the pumping channel 711a. On the other hand, the channels 711a are oriented to accept coating material scattered from gas-phase collision, e.g., particle 723′, to pump such scattered material out of the secondary enclosure. This helps maintaining the secondary environment clean and reduces the possibility of scattered material from later landing on the substrate.

FIG. 8 illustrates an example of the pumping channel according to an embodiment of the invention. As is implied by the callout, the arrangement illustrated in FIG. 8 can be used in the embodiment illustrated in FIG. 7. As shown in FIG. 8, interior pumping channel or hole 811a is of larger diameter than exterior pumping channel or hole 811b. The diameter of hole 811a is designed such that sputtered species 823 may adhere to the entrance of the hole, but the buildup will not occlude the hole, since the diameter is large enough to allow for buildup without hole occlusion. On the other hand, exterior hole 811b is made sufficiently narrow so as to prevent contaminant species 827 from entering the pumping channel. Also, the interior and exterior holes are each made at an oblique angle to the surface of the wall 817, to further prevent introduction of contaminants.

For ease of manufacture, enclosure 817 of the embodiment of FIG. 8 is manufactured as two parts, interior wall 817a having holes 811a drilled therein and exterior wall 817b having exterior holes 811b drilled therein. The exterior wall 817b and interior wall 817a are assembled together and aligned such that the exterior holes 817b are aligned with the interior holes 817a. Also, in the embodiment of FIG. 8 the interior wall 817a is thicker than the exterior wall 811b, such that interior holes 811a are longer than exterior holes 811b. This ensures that interior holes 811a can withstand long processing time without occluding.

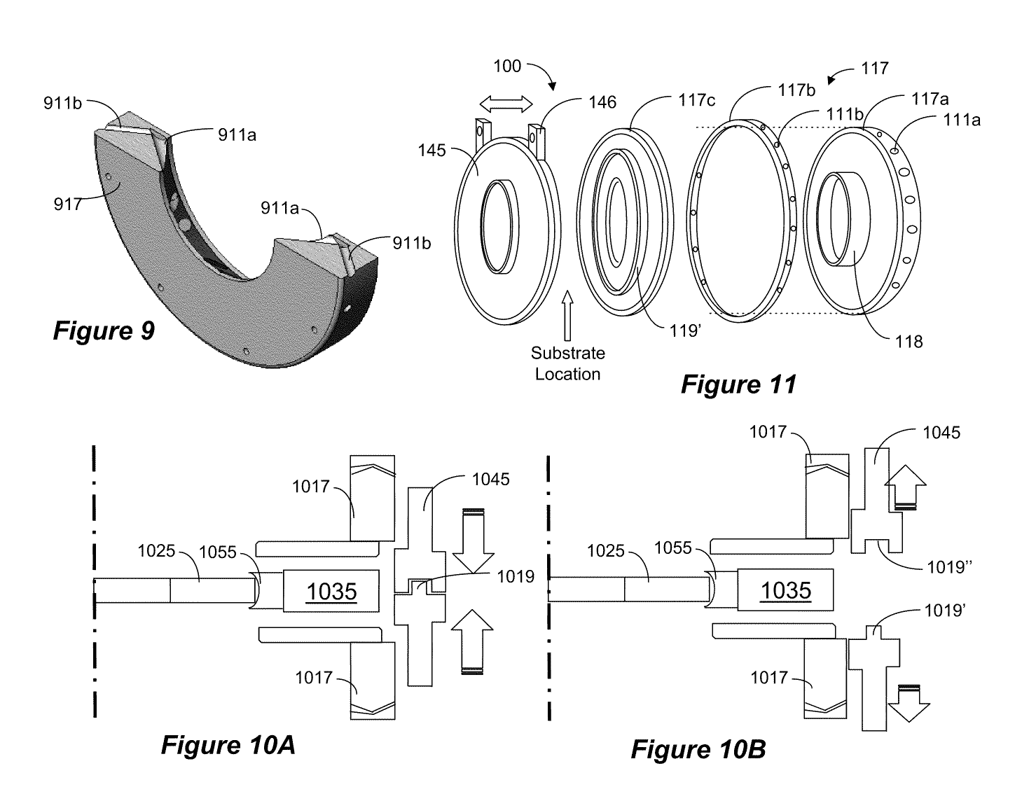

FIG. 9 illustrates a cross-section of a secondary enclosure wall 917 which, in this example, is made of a single part. As can be understood, the cross section is taken at the center of the enclosure wall, as in this embodiment the enclosure wall is circular. Interior pumping holes 911a are shown having large diameter and in a rather conical shape. Exterior pumping holes 911b have a smaller diameter, which is constant throughout the length of the hole. When the two holes connect, they form a somewhat v shape.

FIGS. 10A and 10B illustrate an actuated seal according to an embodiment of the invention. Disk 1025 is held by carrier 1035 via clip 1055. Secondary chamber wall 1017 encloses the disk 1025 and carrier 1035 so as to create a mini-environment within the processing chamber. To seal off the mini environment from the interior of the processing chamber, a movable labyrinth seal 1045 is implemented. In FIG. 10A the actuated seal 1045 in its engaged position, sealing off the interior of secondary enclosure from the interior of the processing chamber. In this condition the disk 1025 can be processed. FIG. 10B illustrates the actuated seal 1045 in its retracted position. In this position, the processed disk 1025 can be removed from the chamber and a new disk loaded for processing.

A shown in this embodiment, the actuated seal 1045 is a labyrinth seal. That is, rather than implementing a contact seal, which may lead to generation of particles, a labyrinth seal is formed with the two parts of the seal, such that gas movement is restricted by a maze. That is, one part of the seal has an extrusion 1019′ that fits into a corresponding indentation 1019″ on the other side of the seal. As can be appreciated, in FIG. 10A, any gas molecule that attempts to travel from the outside into the mini-environment through the labyrinth seal has to perform four 90° turns. Thus, even thought the two parts of the actuated seal 1045 do not contact even in its sealed position, gas leakage is greatly reduced.

FIG. 11 is an exploded view illustrating a secondary enclosure (i.e., mini-environment) having a movable labyrinth seal 145, according to an embodiment of the invention. In FIG. 11 the secondary enclosure is formed using four parts. Enclosure wall 117 is formed of two parts, interior wall 117a and exterior wall 117b, similar to the arrangement illustrated in FIG. 8. As shown, the interior pumping channels 111a are obliquely drilled on the interior wall 117a, while the exterior pumping channels 111b are obliquely drilled on the interior wall 117b. When exterior wall 117b is fitted over interior wall 117a (note exterior diameter of interior wall 117a matches the interior diameter of exterior wall 117b), exterior channels 111b align with interior channels 111a. Interior channels 111a are of larger diameter than exterior channels 111b. Interior wall part 117a also includes an extension 118, which corresponds to the conical section of wall 617 illustrated in FIG. 6. The extension 118 forms the mini environment up to very close proximity to the disk.

A third wall part, 117c is fitted to the interior wall part 117a. In this embodiment, third part 117c is a stationary part of the labyrinth seal. An extrusion 119′ is formed on the face of part 117a, so as to generate the extruded part of the labyrinth seal 119. A corresponding indentation (not shown) is formed on the movable part of seal 145.

The substrate to be processed is positioned beyond the third wall part 117c and the movable seal 145, as indicated by the arrow in FIG. 11. In this manner, the pumping channels are positioned away from the substrate, so that gas flow is diverted away from the substrate to avoid contamination. Once the substrate is positioned for processing, the actuated seal 145 encloses the substrate and seals the secondary environment created by the walls 117a-c. Actuated seal 145 has extensions 146 that are coupled to actuators that move the seal 145 to enable transport of the substrate in retracted position and processing of the substrate in the extended position.

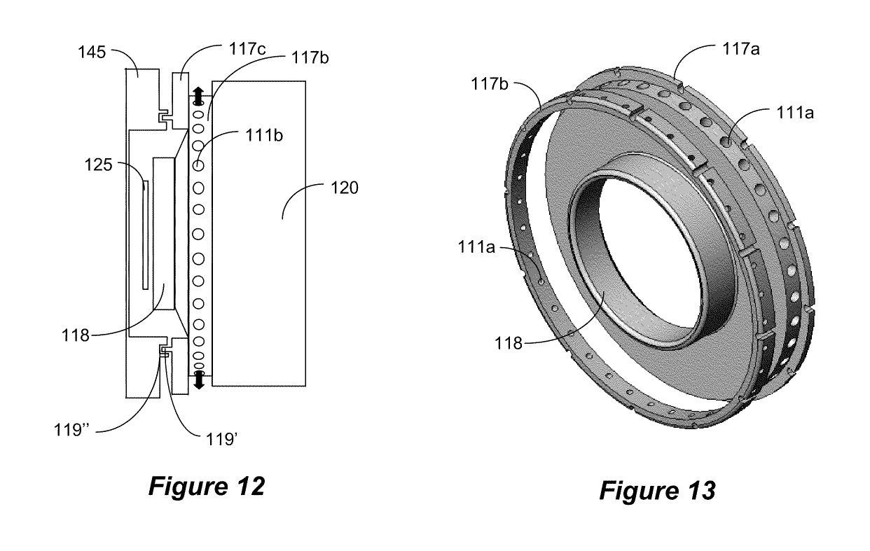

FIG. 12 illustrates an embodiment of the secondary enclosure with the labyrinth seal. In the example of FIG. 12, the enclosure part of the mini environment covers the space between the source 120 and enclosing the disk 125. In this example, only one side of the disk is processed, but it can be appreciated that by duplicating the elements of FIG. 12 one can provide a system for processing both sides of the disk.

In this example the wall section is also fabricated of several part. Exterior wall 117b is fitted over interior wall 117a, only the extension 118 of which is visible. Holes 111b are aligned with holes 111a, which are not visible. Section 117c is a fixed part of the labyrinth seal and has an extension 119′, which fits into indentation 119″ which is provided on the movable part 145 of the seal.

FIG. 13 illustrates the construction of the enclosure wall of two parts with mating holes, according to an embodiment of the invention. Interior wall 17 is shown with large diameter holes 111a and extension 118. Exterior wall is in the form of a ring 117b, and is shown with smaller diameter holes 117.

According to embodiments of the invention, additional pumping devices, such as cryo-panels and/or Meissner coils which preferentially capture water vapors, can be installed near the exhaust channels of the secondary enclosure to further reduce the probability of the contaminants reaching the substrate.

It should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. It is intended that the specification and examples be considered as exemplary only, with a true scope and spirit of the invention being indicated by the following claims.

1. An enclosure for generating a secondary environment within a vacuum processing chamber for coating a substrate; comprising:
an enclosure wall forming a secondary environment within interior of the processing chamber and encompassing the coating source, plasma, and the substrate, and separating them from the interior of the processing chamber, the enclosure wall having a plurality of pumping channels positioned remotely from the substrate, for diverting gaseous flow away from the substrate.

2. The enclosure of claim 1, further comprising a movable seal that opens to transport the substrate to the secondary environment and closes to seal the secondary environment about the substrate.

3. The enclosure of claim 1, further comprising gas inlet to introduce process gas into the secondary environment so as to ensure positive pressure gradient inside the secondary environment versus that outside of the secondary environment.

4. The enclosure of claim 1, wherein the pumping channels are oriented at an oblique angle to the surface of the enclosure wall.

5. The enclosure of claim 1, wherein the pumping channels comprise interior channels of a first diameter oriented at an oblique angle to the surface of the enclosure wall and having one end exposed to the interior of the secondary environment, and exterior channels of a second diameter oriented at a second oblique angle to the surface of the enclosure wall and having one end exposed to the exterior of the enclosure wall, wherein the other end of the interior channel are in fluid communication with the other end of the exterior channels.

6. The enclosure of claim 5, wherein the first diameter is larger than the second diameter.

7. The enclosure of claim 6, wherein first diameter is variable such that the interior channels are conical.

8. The enclosure of claim 6, further comprising a movable seal.

9. The enclosure of claim 1, wherein the pumping channels have a first diameter at one end opened to the interior of the secondary environment and a second diameter at another end opened to exterior of the secondary environment, and wherein the first diameter is larger than the second diameter.

10. The enclosure of claim 1, wherein the enclosure wall comprises an interior part having interior pumping channels of a first diameter and an exterior part fitting over the interior part and having exterior pumping channels of a second diameter.

11. The enclosure of claim 10, wherein the interior pumping channels are oriented at a first oblique angle and the exterior pumping channels are oriented at a second oblique angle, such that when the interior pumping channels and the exterior pumping channels are in fluid communication they for a V-shape channel.

12. The enclosure of claim 11, wherein the enclosure wall further comprises an extension part coupled to the interior part.

13. The enclosure of claim 12, further comprising a movable seal structured to form a seal with the extension part in an extended position.

14. The enclosure of claim 1, further comprising a labyrinth seal.

15. A plasma processing chamber for processing substrates, comprising:
a main chamber body having an opening for vacuum pumping;
a thin-film coating source positioned inside the main chamber body;
a secondary enclosure positioned inside the main chamber body and selectively assuming a transport position and processing position, wherein in its transport position the secondary enclosure enables transport of substrates into the secondary enclosure and in its processing position the secondary enclosure sealingly encloses the thin-film coating source and the substrate, and wherein the secondary enclosure comprises pumping channels providing fluid communication from the interior of the secondary enclosure to outside the secondary enclosure but within the interior of the main chamber body and positioned so as to divert gaseous flow away from the substrate.

16. The plasma processing chamber of claim 15, wherein the secondary enclosure comprises an enclosure wall and an actuated seal.

17. The plasma processing chamber of claim 16, wherein the pumping channels comprise interior channels of a first diameter oriented at an oblique angle to interior surface of the enclosure wall and having fluid communication to the interior of the secondary enclosure, and exterior channels of a second diameter oriented at a second oblique angle exterior surface of the enclosure wall and having fluid communication to the interior of the processing chamber, wherein the interior channels and the exterior channels are in mutual fluid communication.

18. The plasma processing chamber of claim 17, wherein the interior pumping channels connect to the exterior pumping channels to form v-shaped channels.

19. The plasma processing chamber of claim 17, wherein the first diameter is larger than the second diameter.

20. The plasma processing chamber of claim 17, wherein the interior pumping channels are oriented toward the substrate and away from the thin-film coating source, so as to receive scattered coating materials from the substrate.

21. The plasma processing chamber of claim 17, wherein the secondary enclosure encompasses a plasma zone, and wherein the interior pumping channels are positioned within the plasma zone and away from the substrate.

22. The plasma processing chamber of claim 15, wherein the secondary enclosure further comprises an actuated labyrinth seal.
